(19) United States
(12) Patent Application Publication
(10) Pub. No.: US 2002/0153579 A1
(43) Pub. Date: Oct. 24, 2002

(54) Semiconductor device with thin film having high permittivity and uniform thickness

(75) Inventor: Ichiro Yamamoto, Tokyo (JP)

Correspondence Address: YOUNG & THOMPSON, 745 SOUTH 23RD STREET 2ND FLOOR, ARLINGTON, VA, 22202

(73) Assignee: NEC CORPORATION, TOKYO (JP)

(21) Appl. No.: 10/125,370

(22) Filed: Apr. 19, 2002

(30) Foreign Application Priority Data
Apr. 19, 2001 (JP) 2001-120485

(51) Int. Cl. H01L 29/76; H01L 21/336; H01L 29/94; H01L 31/062; H01L 31/113; H01L 21/3205

(52) U.S. Cl. 257/412; 438/287; 438/591; 438/785; 257/410; 257/411

(57) ABSTRACT

A semiconductor device with a thin film having a high dielectric constant and uniform film thickness. The semiconductor device comprises, in an embodiment, an electrode which is made of a metal or a metal nitride and which is formed on a silicon layer via a dielectric film. The dielectric film has a multi-layer structure comprising an amorphous oxide film on the side of the silicon layer and a metal oxide film on the side of the electrode. In another embodiment, the semiconductor device comprises an electrode which is made of silicon (Si) or a silicon germanium (SiGe) and which is formed on a silicon layer via a dielectric film. In such case, the dielectric film has a multi-layer structure comprising a first amorphous oxide film on the side of the silicon layer, a second amorphous oxide film on the side of the electrode, and a metal oxide film between the first and second amorphous oxide films.

### FIELD OF THE INVENTION

The present invention relates generally to a semiconductor device which includes a thin film having a high permittivity or dielectric constant, a method of manufacturing the same, and an apparatus for forming a thin dielectric film having high permittivity.

### BACKGROUND OF THE INVENTION

A silicon oxide film has widely been used as a gate insulating film of a MOSFET (Metal-Oxide-Semiconductor Field-Effect Transistor). This is because, the silicon oxide film has a high stability in a manufacturing process thereof and a good insulating characteristic. Recently, since a semiconductor device becomes more and more minute and highly integrated, it is required that thickness of the gate insulating film is further reduced. Therefore, from the requirements according to a scaling law, it becomes necessary to form the silicon oxide film in a thickness of several nanometers or smaller. However, when such silicon oxide film having an extremely small thickness is used as the gate insulating film, a tunnel current when a gate bias voltage is applied becomes a value which is not negligible with respect to a source/drain current, and becomes a hindrance to obtaining a high performance and a low power consumption of a MOSFET.

Therefore, as a method of reducing an effective film thickness of a gate insulating film and of suppressing the tunnel current, a method is considered in which, in place of the silicon oxide film having a relative dielectric constant of 3.9, thin film material having a relative dielectric constant equal to or larger than 6 is used as the gate insulating film. Candidates for such thin film material having a high dielectric constant include Al₂O₃, ZrO₂ or HfO₂, oxides of rare-earth elements such as Y₂O₃, and the like, and oxides of lanthanoid elements.

Here, with reference to FIG. 9 and FIG. 10, an explanation will be made on conventional MOSFET's which use the abovementioned thin film material having a high dielectric constant. FIG. 9 is a cross sectional view of an example of a conventional MOSFET which uses thin film material having a high dielectric constant. FIG. 10 is a cross sectional view of another example of a conventional MOSFET which uses thin film material having a high dielectric constant.

The MOSFET shown in FIG. 9 has a silicon substrate 1 in which source and drain regions 2 are formed and on which a gate insulating film 18 is formed. The gate insulating film 18 is made of aluminum oxide (Al₂O₃) which is an amorphous oxide. On the gate insulating film 18, a gate electrode 5a made of a metal is formed. Also, the MOSFET shown in FIG. 10 has a silicon substrate 1 in which source and drain regions 2 are formed and on which a gate insulating film is formed. The gate insulating film has two layer structure made of a silicon oxide film 17 which is formed on the silicon substrate 1 and a zirconium oxide (ZrO₂) film 19 which is a crystalline oxide and which is formed on the silicon oxide film 17. On the zirconium oxide film 19, a gate electrode 5a made of a metal is formed.

In the above-mentioned structures, by using aluminum oxide (Al₂O₃) having a relative dielectric constant of approximately 10 or by using zirconium oxide (ZrO₂) having a relative dielectric constant of 25, it is possible to decrease an SiO₂ reduced film thickness, when compared with the structure in which the insulating film is constituted only by using the silicon oxide film.

Each of the above-mentioned thin film materials having high dielectric constant has superior characteristics as a gate insulating film. However, the crystalline oxide such as zirconium oxide (ZrO₂) having a large relative dielectric constant has a problem that, when a film of such crystalline oxide is formed directly on a silicon (Si) substrate, the film is islanded, that is, the crystalline oxide forms many separate island like portions, and it is impossible to obtain the film having a uniform film thickness. Therefore, in order to use such crystalline oxide as a material of the gate insulating film, it is necessary to form, as shown in FIG. 10, the silicon oxide film 17 at the interface between the silicon substrate 1 and the film of such crystalline oxide, i.e., the zirconium oxide (ZrO₂) film 19.

However, when the silicon oxide film 17 which has a very low relative dielectric constant compared with that of the crystalline oxide is formed at the interface, an effective insulating film thickness, that is, a reduced film thickness increases. Also, since the silicon oxide film 17 is pervious to oxygen, oxygen is supplied to the silicon substrate 1 via the silicon oxide film in a heat treatment process thereafter and the silicon oxide film grows. Therefore, for example, even if it is desired to form an insulating film having a reduced film thickness of approximately 1 nm (10 angstroms), the silicon oxide film 17 grows to a film thickness of approximately 0.6 nm (6 angstroms) and it becomes impossible to form a gate insulating film having a desired film thickness and having desired characteristics.

In order to solve such problem, it is also possible to use amorphous metal oxide such as aluminum oxide (Al₂O₃) in place of the crystalline oxide. The amorphous metal oxide such as aluminum oxide (Al₂O₃) can be directly formed on the silicon substrate 1. However, although the relative dielectric constant of the amorphous metal oxide is larger than that of the silicon oxide film 17, the relative dielectric constant of the amorphous metal oxide is at most approximately 10, and is considerably lower than that of the crystalline oxide such as zirconium oxide (ZrO₂). Therefore, it is difficult to cope with further miniaturization of semiconductor devices hereafter.

Also, in case the crystalline oxide such as zirconium oxide (ZrO₂) is formed via the silicon oxide film 17, when the gate electrode formed on the crystalline oxide is made of Si or SiGe, a reducing atmosphere in forming a Si or SiGe film acts on grain boundary of ZrO₂ and, thereby, ZrO₂ is partially reduced. Also, in an impurity ion implantation process or an annealing process performed on Si or SiGe, there is a possibility that Zr and Si react with each other and, as a result thereof, the capacitance of a capacitor using such dielectric film is deteriorated and a leakage current increases due to short-circuiting.

Further, the above-mentioned problems occur not only in the gate insulating film of the MOSFET, but also in a capacitor insulating film used in a semiconductor memory device such as a DRAM (Dynamic Random Access Memory) device and the like. That is, in the semiconductor memory device such as the DRAM and the like, according to an increase in a degree of integration of the device, it is desired to increase the capacitance of each capacitor to improve soft error immunity and the like, although the area that can be occupied by the capacitor becomes increasingly small.

As a method of increasing the capacitance of a capacitor, there is known a technology of forming HSG (Hemi-Spherical Grains) in the capacitor, and the like. By using the HSG technology, it is possible to form a capacitor which comprises capacitor electrodes each having twice the area of a flat capacitor electrode. However, it is still impossible to sufficiently increase an integration degree of the DRAM device only by increasing the area of each capacitor electrode. Therefore, in order to cope with an increase in an integration degree of the DRAM device, a method is considered in which the above-mentioned material having a high dielectric constant is used for forming a capacitor insulating film. However, when the capacitor has a structure in which the crystalline oxide is formed on a lower electrode made of polycrystalline silicon (polysilicon) or in which an upper electrode made of polycrystalline silicon is formed on the crystalline oxide, there arise the problems as follows. That is, the crystalline oxide can not be formed directly on the lower electrode, or, when the upper electrode is formed on the crystalline oxide, the insulation capacity is deteriorated.

### SUMMARY OF THE INVENTION

Therefore, it is an object of the present invention to provide a semiconductor device having a thin film which has a high dielectric constant and has sufficient performance for use in a high density integrated circuit device, and to provide a method of manufacturing such semiconductor device.

It is another object of the present invention to provide a semiconductor device having a thin film which has a high dielectric constant and has sufficient performance as a gate insulating film of a MOSFET, a capacitor insulating film of a DRAM device or the like having a high integration degree, and to provide a method of manufacturing such semiconductor device.

It is still another object of the present invention to provide a semiconductor device having a thin film which has a high dielectric constant and has a uniform thickness for use in a high density integrated circuit device, and to provide a method of manufacturing such semiconductor device.

It is still another object of the present invention to provide a film forming system for efficiently forming a thin film which has a high dielectric constant and a uniform film thickness and which has sufficient performance for use in a high density integrated circuit device.

It is still another object of the present invention to obviate the disadvantages of the conventional semiconductor device with a thin film having a high dielectric constant and the conventional method of manufacturing such semiconductor device.

According to an aspect of the present invention, there is provided a semiconductor device comprising: a silicon layer; and an electrode which is made of a metal or a metal nitride and which is formed on the silicon layer via a dielectric film interposed therebetween; wherein the dielectric film has a multi-layer structure comprising an amorphous oxide film on the side of the silicon layer and a metal oxide film on the side of the electrode.

In this case, it is preferable that the amorphous oxide film is made of a metal oxide selected from a group including at lease Al₂O₃.

It is also preferable that the thickness of the amorphous oxide film is in a range of 2-20 angstroms.

It is further preferable that the thickness of the amorphous oxide film is in a range of 5-10 angstroms.

It is advantageous that the metal oxide film comprises a stack of one or more films of materials selected from a group consisting of ZrO₂, HfO₂, TiO₂, Ta₂O₅, BST, STO, PZT and mixtures of these materials with Al₂O₃.

It is also advantageous that the thickness of the metal oxide film is in a range of 10-50 angstroms.

It is further advantageous that the metal oxide film or the amorphous oxide film disposed on the side of the silicon layer is formed by using an ALD system.

It is preferable that the dielectric film is formed as a gate insulating film of a MOSFET in the semiconductor device.

It is also preferable that the semiconductor device is a DRAM device and the dielectric film is formed as an insulating film of a capacitor of the DRAM device.

According to another aspect of the present invention, there is provided a semiconductor device comprising: a silicon layer; and an electrode which is made of silicon (Si) or silicon germanium (SiGe) and which is formed on the silicon layer via a dielectric film interposed therebetween; wherein the dielectric film has a multi-layer structure comprising a first amorphous oxide film on the side of the silicon layer, a second amorphous oxide film on the side of the electrode, and a metal oxide film interposed between the first and second amorphous oxide films.

In this case, it is preferable that the first amorphous oxide film is made of a metal oxide selected from a group including at least SiO₂ and Al₂O₃, and wherein the second amorphous oxide film is made of a metal oxide selected from a group including at least Al₂O₃.

It is also preferable that the thickness of the first or second amorphous oxide films is in a range of 2-20 angstroms.

It is further preferable that the thickness of the first or second amorphous oxide films is in a range of 5-10 angstroms.

It is advantageous that the metal oxide film comprises a stack of one or more films of materials selected from a group consisting of ZrO₂, HfO₂, TiO₂, Ta₂O₅, BST, STO, PZT and mixtures of these materials with Al₂O₃.

It is also advantageous that the thickness of the metal oxide film is in a range of 10-50 angstroms.

It is further advantageous that the metal oxide film or at least the first amorphous oxide film disposed on the side of the silicon layer is formed by using an ALD system.

It is preferable that the dielectric film is formed as a gate insulating film of a MOSFET in the semiconductor device.

It is also preferable that the semiconductor device is a DRAM device and the dielectric film is formed as an insulating film of a capacitor of the DRAM device.

According to still another aspect of the present invention, there is provided a method of manufacturing a semiconductor device having a silicon layer, an electrode which is made of a metal or a metal nitride and which is formed on the silicon layer via a dielectric film interposed therebetween, wherein the dielectric film has a multi-layer structure comprising an amorphous oxide film on the side of the silicon layer and a metal oxide film on the side of the electrode, said method comprising: before forming the amorphous oxide film, terminating the surface of the silicon layer with hydrogen; and after separating hydrogen from the surface of the silicon layer, forming the amorphous oxide film on the silicon layer.

In this case, it is preferable that the separating hydrogen from the surface of the silicon layer and the forming the amorphous oxide are performed within a common chamber.

It is also preferable that the amorphous oxide film is made of a metal oxide selected from a group including at least Al₂O₃.

It is further preferable that the metal oxide film comprises a stack of one or more films of materials selected from a group consisting of ZrO₂, HfO₂, TiO₂, Ta₂O₅, BST, STO, PZT and mixtures of these materials with Al₂O₃.

It is advantageous that the metal oxide film or the amorphous oxide film disposed on the side of the silicon layer is formed by using an ALD system.

It is also advantageous that the dielectric film is formed as a gate insulating film of a MOSFET in the semiconductor device.

It is further advantageous that the semiconductor device is a DRAM device and the dielectric film is formed as an insulating film of a capacitor of the DRAM device.

According to still another aspect of the present invention, there is provided a method of manufacturing a semiconductor device having a silicon layer, an electrode which is made of silicon (Si) or silicon germanium (SiGe) and which is formed on the silicon layer via a dielectric film interposed therebetween, wherein the dielectric film has a multi-layer structure comprising a first amorphous oxide film on the side of the silicon layer, a second amorphous oxide film on the side of the electrode, and a metal oxide film interposed between the first and second amorphous oxide films, said method comprising: before forming the first amorphous oxide film, terminating the surface of the silicon layer with hydrogen; and after separating hydrogen from the surface of the silicon layer, forming the first amorphous oxide film on the silicon layer.

In this case, it is preferable that the separating hydrogen from the surface of the silicon layer and the forming the first amorphous oxide film are performed within a common chamber.

It is also preferable that the first amorphous oxide film is made of a metal oxide selected from a group including at least SiO₂ and Al₂O₃, and wherein the second amorphous oxide film is made of a metal oxide selected from a group including at least Al₂O₃.

It is further preferable that the metal oxide film comprises a stack of one or more films of materials selected from a group consisting of ZrO₂, HfO₂, TiO₂, Ta₂O₅, BST, STO, PZT and mixtures of these materials with Al₂O₃.

It is advantageous that the metal oxide film or the first amorphous oxide film disposed on the side of the silicon layer is formed by using an ALD system.

It is also advantageous that the dielectric film is formed as a gate insulating film of a MOSFET in the semiconductor device.

It is further advantageous that the semiconductor device is a DRAM device and the dielectric film is formed as an insulating film of a capacitor of the DRAM device.

According to still another aspect of the present invention, there is provided a system for forming a dielectric film comprising: a heating chamber portion for separating hydrogen which terminates a surface of a workpiece of a semiconductor device; and a film forming chamber portion for forming the dielectric film on the surface of the workpiece on an atomic layer level; wherein the heating chamber portion and the film forming chamber portion communicate with each other, and a process of separating hydrogen from the surface of the workpiece and a process of forming the dielectric film on the surface of the workpiece can be performed continuously.

### BRIEF DESCRIPTION OF THE DRAWINGS

These and other features, and advantages, of the present invention will be more clearly understood from the following detailed description taken in conjunction with the accompanying drawings, in which like reference numerals designate identical or corresponding parts throughout the figures, and in which:

FIG. 1 is a cross sectional view illustrating a schematic structure of a gate portion of a MOSFET in a semiconductor device according to a first embodiment of the present invention;

FIG. 2A through FIG. 2D are cross sectional views each illustrating a structure of a workpiece of the MOSFET shown in FIG. 1 during a process of manufacturing the same;

FIG. 3 is a cross sectional view illustrating a schematic structure of a gate portion of a MOSFET in a semiconductor device according to a second embodiment of the present invention;

FIG. 4A through FIG. 4E are cross sectional views each illustrating a structure of a workpiece of the MOSFET shown in FIG. 3 during a process of manufacturing the same;

FIG. 5A through FIG. 5C are partial cross sectional views illustrating various other structures of gate portions of MOSFET's according to the present invention;

FIG. 6 is a cross sectional view illustrating a schematic structure of a capacitor portion of a DRAM device according to a third embodiment of the present invention;

FIG. 7A through FIG. 7D are cross sectional views each illustrating a structure of a workpiece of the capacitor shown in FIG. 6 during a process of manufacturing the same;

FIG. 8 is a cross sectional view showing a schematic structure of an ALD system according to a fourth embodiment of the present invention;

FIG. 9 is a cross sectional view showing an example of a conventional MOSFET which includes a thin dielectric film having a high dielectric constant; and

FIG. 10 is a cross sectional view of another example of a conventional MOSFET which includes a thin dielectric film having a high dielectric constant.

### DESCRIPTION OF A PREFERRED EMBODIMENT

A semiconductor device including a thin film having a high dielectric constant according to the present invention has, as an embodiment thereof, a two layer structure comprising a first dielectric film which is formed on a silicon (Si) substrate or layer and which is made of amorphous oxide such as aluminum oxide (Al₂O₃) and the like and a second dielectric film which is formed on the first dielectric film and which is made of crystalline oxide or metal oxide such as zirconium oxide (ZrO₂), hafnium oxide (HfO₂), and the like. On such two layer structure, an electrode made of a metal and the like is formed. In other embodiment, a semiconductor device including a thin film having a high dielectric constant according to the present invention has a three layer structure further comprising a third dielectric film which is formed on the above-mentioned second dielectric film and which is made of amorphous oxide such as aluminum oxide (Al₂O₃) and the like. Further, an electrode made of a metal, silicon (Si) and the like is formed on the three layer structure. In this way, by interposing amorphous oxide between metal oxide and silicon (Si), it is possible to form a film of metal oxide with uniform film thickness. It is also possible to suppress reaction between Zr and the like and Si in a reducing atmosphere when forming an electrode and/or in a impurity ion implantation process and a heat treatment process. Thereby, it is possible to avoid an increase in a leakage current and a decrease in capacitance.

Now, with reference to the drawings, the abovementioned embodiments of the present invention will be explained in more detail.

[Embodiment 1]

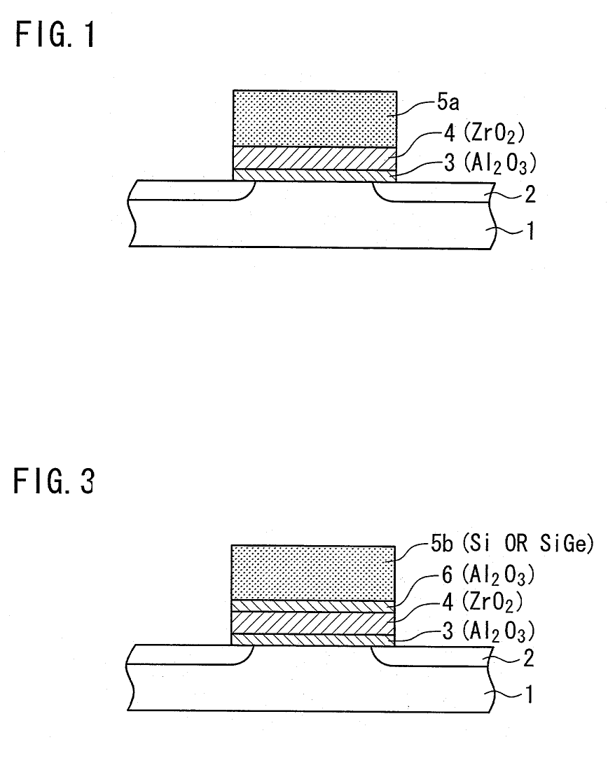

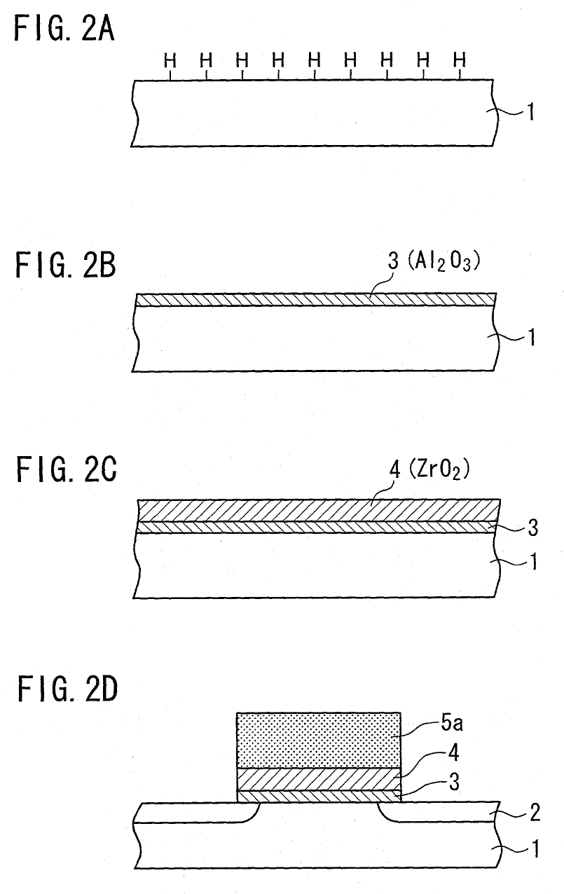

With reference to FIG. 1 and FIGS. 2A-2D, an explanation will be made on a semiconductor device including a thin film having a high dielectric constant, and on a method of manufacturing such semiconductor device, according to the first embodiment of the present invention. FIG. 1 is a cross sectional view illustrating a schematic structure of a gate portion of a MOSFET in the semiconductor device according to the first embodiment of the present invention. FIG. 2A through FIG. 2D are cross sectional views each illustrating a structure of a workpiece of the MOSFET shown in FIG. 1 during a process of manufacturing the same. In the following, an explanation will be given on an example in which a thin film having a high dielectric constant and having a stacked structure is applied to a gate insulating film of a MOSFET. Since portions other than a gate portion has a structure similar to those of a general MOSFET, an explanation thereof is omitted here.

As shown in FIG. 1, the MOSFET according to the present embodiment has a gate insulating film which has a multi-layer structure and which is formed on a silicon substrate 1. A gate electrode Sa made of a metal is formed on the gate insulating film. The gate insulating film comprises a first dielectric film 3 which is formed on the silicon (Si) substrate 1 and which is made of amorphous oxide, in this case, amorphous metal oxide, such as aluminum oxide (Al₂O₃) and the like and a second dielectric film 4 which is formed on the first dielectric film 3 and which is made of metal oxide such as zirconium oxide (ZrO₂) and the like. The silicon substrate 1 also has source/drain regions 2 formed on both sides of the gate electrode Sa by implanting predetermined impurity into the silicon substrate 1.

As described above in the “Background of the Invention”, when a film of the crystalline oxide or metal oxide such as zirconium oxide (ZrO₂) and the like having a high dielectric constant is formed directly on the silicon substrate, the film is islanded, and it is impossible to obtain the film having a uniform film thickness. Therefore, in the prior art, the crystalline oxide was formed on the silicon substrate via a silicon oxide film. However, when the silicon oxide film exists between the crystalline oxide film and the silicon substrate, the relative dielectric constant of the dielectric film having a multilayer structure becomes much reduced as a whole, and it becomes impossible to obtain a desired performance as a gate insulating film.

On the other hand, the inventor of the present invention has confirmed that a film of the crystalline oxide or metal oxide such as ZrO₂ can not be formed directly on the silicon substrate 1 with uniform thickness, but the film of the crystalline oxide or metal oxide such as ZrO₂ can be formed flat on the amorphous oxide such as Al₂O₃ and the like without islanding the film and with uniform thickness. By using a structure in which the amorphous oxide such as Al₂O₃ and the like is interposed between the silicon substrate 1 and the film of the metal oxide such as ZrO₂ and the like, it is possible to form the film of the metal oxide on the silicon substrate 1 without using a silicon oxide film.

In the above structure, since the relative dielectric constant of Al₂O₃ is relatively large when compared with that of the silicon oxide film, it is possible to decrease a reduced film thickness of the stacked film as a whole. Also, since an Al₂O₃ film is hard to transmit oxygen, even in a high temperature atmosphere in which the metal oxide and/or the gate electrode is formed on the Al₂O₃ film, oxygen is not supplied to the silicon substrate 1. Therefore, it is possible to suppress formation of a silicon oxide film at the interface between the Al₂O₃ film and the silicon substrate 1, and to obviate the problem of the prior art example that a film thickness of the silicon oxide film increases.

With reference to the drawings, an explanation will now be made on an exemplary method of forming the gate insulating film having the above-mentioned multi-layer structure. FIG. 2A through FIG. 2D are cross sectional views each illustrating a structure of a workpiece obtained during a process of forming a MOSFET including the gate insulating film having the abovementioned multi-layer structure.

First, by using a Local Oxidation of Silicon (LOCOS) method, a Shallow Trench Isolation (STI) method or the like, an element isolation insulating film (not shown in the drawing) is formed on a silicon substrate 1. Then, at an area isolated by the element isolation insulating film, the silicon substrate 1 is treated by Diluted Hydrofluoric Acid (DHF), and thereby the surface of the silicon substrate 1 is terminated by hydrogen. This treatment for terminating the surface of the silicon substrate 1 by hydrogen avoids formation of an oxide film at the surface of the silicon substrate 1, and maintain the surface of the silicon substrate 1 in clean condition. FIG. 2A shows a condition after the treatment by DHF.

The workpiece is then introduced into an Atomic-Layer Deposition (ALD) system which is also called an Atomic Layer Epitaxial Growth (ALE) system, and heated at a temperature of, for example, approximately 400° C. to separate hydrogen from the surface of the silicon substrate 1. Thereafter, Al(CH₃)₃, and O₃ or H₂O are introduced as material gases into the ALD system, and an Al₂O₃ film 3 is formed as a first dielectric film to a film thickness of 2-20 angstroms (0.2-2 nm), preferably to a film thickness of 5-10 angstroms (0.5-1 nm), at a temperature of approximately 300° C. FIG. 2B shows a condition after forming the Al₂O₃ film 3. The Al₂O₃ film 3 functions as a seed layer for a ZrO₂ film formed thereon, and also functions as oxygen barrier. Thereby, it becomes possible to avoid growth of a silicon oxide film at the interface of the silicon substrate 1 during a heat treatment process thereafter.

The Al₂O₃ film can also be formed by using a thermal CVD method or a sputtering method. However, since the relative dielectric constant of the Al₂O₃ is relatively small when compared with that of the crystalline oxide, it is necessary to form the film of Al₂O₃ as thin as possible and uniformly. Therefore, it is preferable that the Al₂O₃ film is formed by using the ALD system.

Then, ZrCl₄, and O₃ or H₂O are introduced as material gases into the ALD system, and the ZrO₂ film 4 as a second dielectric film is formed to a film thickness of 10-50 angstroms (1-5 nm), at a temperature of approximately 300° C. FIG. 2C shows a condition after forming the ZrO₂ film 4. When growing the ZrO₂ film 4, the Al₂O₃ film functions as a seed layer, so that the ZrO₂ film 4 can be formed uniformly on the Al₂O₃ film and it is possible to avoid islanding of ZrO₂ which occurs when the ZrO₂ film 4 is formed directly on the silicon substrate 1.

Since the ZrO₂ film 4 has a larger film thickness than that of the Al₂O₃ film, it is possible to form the ZrO₂ film 4 not only by using the ALD method, but also by using the thermal CVD method or the sputtering method. Also, the film thickness of the ZrO₂ film 4 may be appropriately adjusted taking the film thickness of the lower Al₂O₃ film into consideration such that the multi-layer film has a desired performance as a whole. In case an HfO₂ film is formed in place of the ZrO₂ film 4, it is possible to use HfCl₄, and O₃ or H₂O are introduced as material gases and to form the HfO₂ film, at a temperature of approximately 300° C.

Thereafter, a film of a metal or metal nitride such as titanium nitride (TiN), aluminum (Al), ruthenium (Ru) and the like is formed by sputtering on the ZrO₂ film 4. The film formed in this way, the ZrO₂ film (second dielectric film 4) and the Al₂O₃ film (first dielectric film 3) are patterned one after another by using a known lithography technology and an etching technology to form a gate portion of the MOSFET which includes a gate electrode 5a. FIG. 2D shows a structure after forming the gate portion. Then, predetermined impurity ions are implanted into the silicon substrate 1 on both sides of the gate portion to form source/drain regions 2.

In this way, according to the gate structure of the MOSFET according to the present embodiment and the method of manufacturing the same, when forming a metal oxide film such as the ZrO₂ film and the like having a high relative dielectric constant, an amorphous dielectric film such as the Al₂O₃ film and the like is formed as a grounding layer. Therefore, the Al₂O₃ film functions as a seed layer for the ZrO₂ film formed thereon, so that it becomes possible to form the ZrO₂ film with uniform film thickness. Also, the Al₂O₃ film functions as oxygen barrier. Therefore, it becomes possible to avoid growth of a silicon oxide film at the interface of the silicon substrate 1 during a heat treatment process when the ZrO₂ film and/or the gate electrode Sa are formed thereafter. Further, since it is not necessary to form a silicon oxide film having a low relative dielectric constant, it becomes possible to decrease the reduced film thickness and to form a thin film which has a high dielectric constant and which has sufficient performance for use in an integrated circuit device having a high integration degree.

[Embodiment 2]

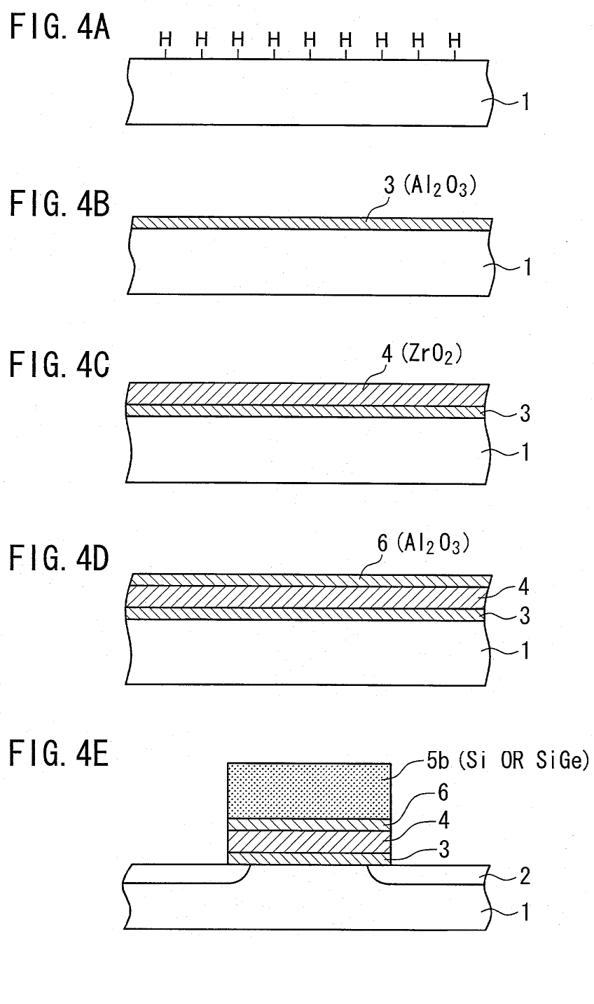

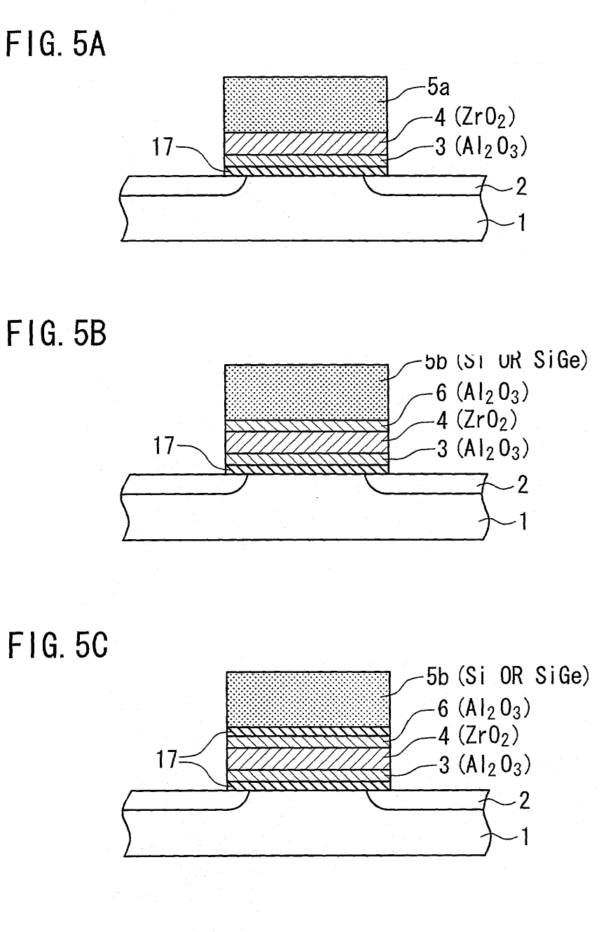

With reference to FIG. 3, FIGS. 4A-4E and FIGS. 5A-5C, an explanation will be made on a semiconductor device including a thin film having a high dielectric constant, and on a method of manufacturing such semiconductor device, according to the second embodiment of the present invention. FIG. 3 is a cross sectional view illustrating a schematic structure of a gate portion of a MOSFET in the semiconductor device according to the second embodiment of the present invention. FIG. 4A through FIG. 4E are cross sectional views each illustrating a structure of a workpiece of the MOSFET shown in FIG. 3 during a process of manufacturing the same. FIG. 5A through FIG. 5C are partial cross sectional views illustrating various other structures of gate portions of MOSFET's according to the present invention.

As shown in FIG. 3, the MOSFET according to the present embodiment has a gate insulating film which has a multi-layer structure and which is formed on a silicon substrate 1. The gate insulating film comprises a first dielectric film 3 which is formed on the silicon (Si) substrate 1 and which is made of amorphous oxide such as aluminum oxide (Al₂O₃) and the like and a second dielectric film 4 which is formed on the first dielectric film 3 and which is made of metal oxide such as zirconium oxide (ZrO₂) and the like. The gate insulating film further has a third dielectric film 6 which is formed on the second dielectric film 4 and which is made of amorphous oxide such as aluminum oxide (Al₂O₃) and the like. A gate electrode 5b made of Si, silicon germanium (SiGe) and the like is formed on the gate insulating film having the above-mentioned multilayer structure. The silicon substrate 1 also has source/drain regions 2 formed on both sides of the gate portion by implanting predetermined impurity into the silicon substrate 1.

As described above in the explanation of the first embodiment, it is impossible to form a flat film of the metal oxide such as zirconium oxide (ZrO₂) and the like having a high dielectric constant directly on the silicon substrate 1. However, a film of the metal oxide such as ZrO₂ can be formed flat on the amorphous oxide such as Al₂O₃ and the like without islanding the film and with uniform thickness. Therefore, in this embodiment, the first dielectric film 3 made of amorphous oxide such as Al₂O₃ and the like is interposed between the silicon substrate 1 and the film of the metal oxide such as ZrO₂ and the like.

Further, when Si or SiGe is used as the material of the gate electrode 5b, if Si or SiGe is directly formed on the film of the metal oxide such as ZrO₂ and the like, the reducing atmosphere in forming a Si or SiGe film acts on grain boundary of ZrO₂. Thereby, ZrO₂ is partially reduced and a leakage current increases. Therefore, in the present embodiment, the third dielectric film 6 which is made of amorphous oxide such as aluminum oxide (Al₂O₃) and the like is further formed on the ZrO₂ film, so that the ZrO₂ film is not exposed directly to the reducing atmosphere in forming the Si or SiGe film and the above-mentioned problem can be obviated.

With reference to the drawings, an explanation will now be made on a method of forming the gate insulating film having the multi-layer structure shown in FIG. 3. FIG. 4A through FIG. 4E are cross sectional views each illustrating a structure of a workpiece obtained during a process of forming a MOSFET including the gate insulating film having the multi-layer structure shown in FIG. 3.

First, in a manner similar to the first embodiment, by using the LOCOS method, the STI method or the like, an element isolation insulating film (not shown in the drawing) is formed on a silicon substrate 1. Then, at an area isolated by the element isolation insulating film, the silicon substrate 1 is treated by DHF, and thereby the surface of the silicon substrate 1 is terminated by hydrogen. This treatment for terminating the surface of the silicon substrate 1 by hydrogen avoids formation of an oxide film at the surface of the silicon substrate 1, and maintain the surface of the silicon substrate 1 in clean condition. FIG. 4A shows a condition after the treatment by DHF.

The workpiece is then introduced into the Atomic-Layer Deposition (ALD) system, and heated at a temperature of, for example, approximately 400° C. to separate hydrogen from the surface of the silicon substrate 1. Thereafter, Al(CH₃)₃, and O₃ or H₂O are introduced as material gases into the ALD system, and an Al₂O₃ film is formed as a first dielectric film 3 to a film thickness of 2-20 angstroms (0.2-2 nm), preferably to a film thickness of 5-10 angstroms (0.5-1 nm), at a temperature of approximately 300° C. FIG. 4B shows a condition after forming the Al₂O₃ film, i.e., the first dielectric film 3. The Al₂O₃ film 3 functions as a seed layer for a ZrO₂ film formed thereon, and also functions as oxygen barrier. Thereby, it becomes possible to avoid growth of a silicon oxide film at the interface of the silicon substrate 1 during a heat treatment process thereafter.

The Al₂O₃ film can also be formed by using a thermal CVD method or a sputtering method. However, in order to obtain uniform quality of the film, it is preferable that the Al₂O₃ film is formed by using the ALD system. Also, in place of the Al₂O₃ film, it is possible to form a very thin thermal oxide film having a thickness of 5-10 angstroms on the silicon substrate 1.

Then, ZrCl₄, and O₃ or H₂O are introduced as material gases into the ALD system, and the ZrO₂ film as a second dielectric film 4 is formed to a film thickness of 10-50 angstroms (1-5 nm), at a temperature of approximately 300° C. FIG. 4C shows a condition after forming the ZrO₂ film as a second dielectric film 4. Similarly to the first embodiment, when growing the ZrO₂ film, the Al₂O₃ film functions as a seed layer, so that the ZrO₂ film can be formed uniformly on the Al₂O₃ film and it is possible to avoid islanding of ZrO₂ which occurs when the ZrO₂ film is formed directly on the silicon substrate 1.

Since the ZrO₂ film has a larger film thickness than that of the Al₂O₃ film, it is possible to form the ZrO₂ film not only by using the ALD method, but also by using the thermal CVD method or the sputtering method.

In the first embodiment mentioned before, a gate electrode made of metal or metal nitride is formed on the ZrO₂ film. However, in the present embodiment, the gate electrode 5b is made of Si or SiGe and, therefore, the gate electrode 5b can not be formed on the the ZrO₂ film directly. Therefore, Al(CH₃)₃, and O₃ or H₂O are again introduced as material gases into the ALD system, and an Al₂O₃ film is formed as a third dielectric film 6, at a temperature of approximately 300° C. FIG. 4D shows a condition after forming the Al₂O₃ film, i.e., the third dielectric film 6. The Al₂O₃ film can also be formed by using a thermal CVD method or a sputtering method. Also, the film thickness of the Al₂O₃ film may be appropriately adjusted such that the multi-layer film has a desired performance as a whole.

Thereafter, a film of Si, SiGe and the like is formed by sputtering on the Al₂O₃ film, i.e., the third dielectric film 6, and implantation of impurity ions and heat treatment are performed. In this case, if the Si, SiGe and the like is formed directly on the film of the crystalline oxide such as ZrO₂ and the like, the reducing atmosphere in forming the gate electrode acts on grain boundary of ZrO₂, and, thereby, ZrO₂ is partially reduced and a leakage current increases. However, in this embodiment, since the Al₂O₃ film is interposed between the ZrO₂ and the film of Si or SiGe, it is possible to prevent the ZrO₂ from being exposed to the reducing atmosphere and to suppress reaction between ZrO₂ and Si. Therefore, the abovementioned problems can be effectively obviated.

Then, the film 5b of Si, SiGe or the like, the Al₂O₃ film (third dielectric film 6), the ZrO₂ film (second dielectric film 4) and the Al₂O₃ film (first dielectric film 3) are patterned one after another by using a known lithography technology and an etching technology to form a gate portion of the MOSFET which includes a gate electrode 5b. FIG. 4E shows a structure after forming the gate portion. Then, predetermined impurity ions are implanted into the silicon substrate 1 on both sides of the gate portion to form source/drain regions 2.

In this way, according to the gate structure of the MOSFET according to the present embodiment and the method of manufacturing the same, when forming the metal oxide film such as the ZrO₂ film and the like having a high relative dielectric constant, an amorphous dielectric film such as the Al₂O₃ film and the like is formed as a grounding layer and a protective layer. Therefore, it is possible to form the crystalline insulating film such as the ZrO₂ film with uniform film thickness. It is also possible to suppress reaction of ZrO₂, in a reducing atmosphere when forming a gate electrode made of Si or SiGe, and in an impurity ion implantation process and a heat treatment process. Thereby, it is possible to avoid an increase in a leakage current and a decrease in capacitance.

In each of the above-mentioned embodiments, a structure is explained in which a silicon oxide film is not formed at the interface with a silicon layer such as the silicon substrate 1 or the gate electrode 5b made of Si or SiGe. However, according to the present invention, for example, the first dielectric film 3 made of Al₂O₃ which is formed at the lower layer functions as oxygen barrier. As a result, a silicon oxide film does not grow at the interface with the silicon layer during a heat treatment process thereafter. Therefore, as long as a desired performance can be attained as a multi-layer insulating film as a whole, it is possible to use a structure in which a silicon oxide film exists between the silicon layer and the Al₂O₃ film.

FIG. 5A through FIG. 5C are partial cross sectional views each illustrating a variation of a structure in which the silicon oxide film exists between the silicon layer and the Al₂O₃ film. In the example of FIG. 5A, a silicon oxide film 17 is interposed between the silicon substrate 1 and the first dielectric film 3 of the structure shown in FIG. 1. In the example of FIG. 5B, a silicon oxide film 17 is interposed between the silicon substrate 1 and the first dielectric film 3 of the structure shown in FIG. 3. In the example of FIG. 5C, silicon oxide films 17 are interposed between the silicon substrate 1 and the first dielectric film 3 and between the third dielectric film 6 and the gate electrode 5b of the structure shown in FIG. 3.

Also, in each of the above-mentioned embodiments, a dielectric film having a multi-layer structure is used as a gate insulating film of a MOSFET. However, the present invention is not limited to such embodiments, but can be applied to any semiconductor device which requires a dielectric film having a high relative dielectric constant. For example, a dielectric film having a high dielectric constant according to the present invention can be applied to an insulating film of a capacitor used in a DRAM device and the like, as shown in a third embodiment mentioned below.

[Embodiment 3]

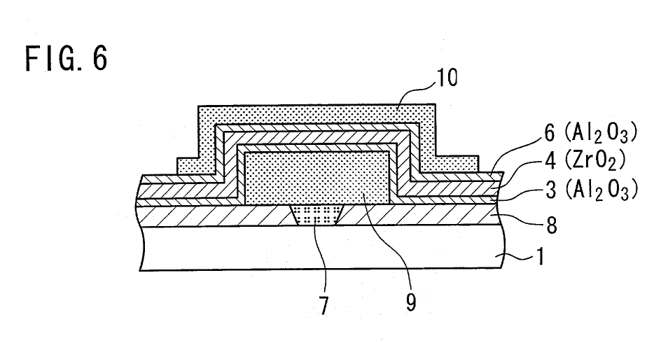

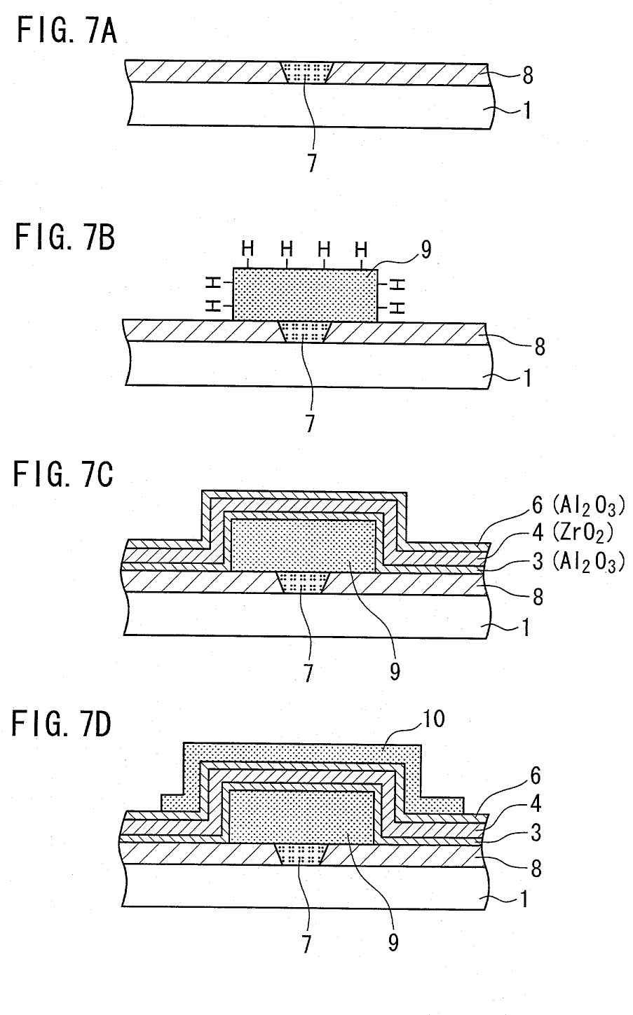

With reference to FIG. 6 and FIGS. 7A-7D, an explanation will be made on a semiconductor device including a thin film having a high dielectric constant, and on a method of manufacturing such semiconductor device, according to the third embodiment of the present invention. FIG. 6 is a cross sectional view illustrating a schematic structure of a capacitor portion of a DRAM device according to the third embodiment of the present invention. FIG. 7A through FIG. 7D are cross sectional views each illustrating a structure of a workpiece of the capacitor shown in FIG. 6 during a process of manufacturing the same. In the present embodiment, the multi-layer structure of the insulating film mentioned above with respect to the first and second embodiments is applied to a capacitor of a DRAM device, particularly to a capacitor having a Semiconductor Insulator Semiconductor (SIS) structure in which each of an upper electrode and a lower electrode formed on both sides of a dielectric film is made of a semiconductor such as polycrystalline silicon (polysilicon) and the like.

As shown in FIG. 6, the capacitor of the DRAM device according to the present embodiment has an insulating film 8 formed on a silicon substrate 1. The insulating film 8 has a plug 7 which fills an opening of the insulating film 8. On the insulating film 8 in an area including the plug 8, there is disposed a lower electrode 9 made of polycrystalline silicon into which impurities are doped and the like. On such lower electrode 9, there is formed a multi-layer dielectric film which comprises first, second and third dielectric films 3, 4 and 6, and which has a stacked structure shown in the second embodiment mentioned above. That is, the multi-layer dielectric film has a structure in which Al₂O₃/ZrO₂/Al₂O₃ films are stacked. Further, on such multi-layer dielectric film, an upper electrode 10 is formed which is made, for example, of polycrystalline silicon into which impurities are doped.

With reference to the drawings, an explanation will now be made on a method of fabricating the capacitor of the DRAM device shown in FIG. 6. FIG. 7A through FIG. 7D are cross sectional views each illustrating a structure of a workpiece obtained during a process of fabricating the capacitor having the multi-layer insulating film shown in FIG. 6. Portions other than the capacitor may have the same structure as that of a general DRAM device, and, therefore, an explanation thereof is omitted here.

First, as shown in FIG. 7A, a silicon substrate 1 on which a transistor not shown in the drawing is formed is prepared. On the silicon substrate 1, an insulating film 8 is formed, and a predetermined opening is formed. Then, polycrystalline silicon which contains impurities is deposited by using, for example, a CVD method, and thereby the opening is filled with the polycrystalline silicon. Also, polycrystalline silicon deposited on portions other than the opening is removed by dry etching. Thereby, the plug 7 is formed as shown in FIG. 7A.

Then, as shown in FIG. 7B, on the insulating film 8 and the plug 7, polycrystalline silicon into which impurities are doped is deposited by using, for example, a CVD method and the like, and the film of the deposited polycrystalline silicon is patterned to form a lower electrode 9. Thereafter, the surface of the lower electrode 9 is terminated by hydrogen, by DHF treatment.

The workpiece is then introduced into the ALD system, and heated at a temperature of, for example, approximately 400° C. to separate hydrogen from the surface of the lower electrode 9. Thereafter, similarly to the second embodiment mentioned above, an Al₂O₃ film is formed as a first dielectric film 3 to a film thickness of 2-20 angstroms (0.2-2 nm), preferably to a film thickness of 5-10 angstroms (0.5-1 nm). Then, a ZrO₂ film as a second dielectric film 4 is formed to a film thickness of 10-50 angstroms (1-5 nm). Further, an Al₂O₃ film is formed as a third dielectric film 6 to a predetermined film thickness.

The Al₂O₃ films can be formed by using Al(CH₃)₃, and O₃ or H₂O as material gases at a temperature of approximately 300° C. The ZrO₂ film can be formed by using ZrCl₄, and O₃ or H₂O as material gases at a temperature of approximately 300° C. In order to obtain uniform quality of the film, it is preferable that the Al₂O₃ film as the first dielectric film 3 is formed by using the ALD system. With respect to the ZrO₂ film and the Al₂O₃ film as the third dielectric film 6, it is possible to form these films not only by using the ALD method, but also by using the thermal CVD method or the sputtering method.

Thereafter, as shown in FIG. 7D, polycrystalline silicon is deposited by using a CVD method, and then implantation of impurity ions and heat treatment are performed. Also, by using a known lithography technology and an etching technology, the polycrystalline silicon film is patterned to form an upper electrode 10. Thereby, the capacitor of the DRAM device according to the present embodiment is formed.

In this way, according to the capacitor structure of the DRAM device according to the present embodiment and the method of manufacturing the same, when forming the metal oxide such as the ZrO₂ film and the like having a high relative dielectric constant, an amorphous dielectric film such as the Al₂O₃ film and the like is formed as a grounding layer and a protective layer. Therefore, it is possible to form the crystalline insulating film such as the ZrO₂ film with uniform film thickness. It is also possible to suppress reaction of ZrO₂, in a reducing atmosphere when forming the upper electrode 10 made of polycrystalline silicon, and in an impurity ion implantation process and a heat treatment process. Thereby, it is possible to avoid an increase in a leakage current and a decrease in capacitance.

In the above-mentioned embodiment, an SIS structure is explained in which each of the upper electrode 10 and lower electrode 9 of the capacitor is made of semiconductor such as polycrystalline silicon and the like. However, the present invention can be applied to a structure in which at least one of the upper electrode 10 and lower electrode 9 is made of polycrystalline silicon. For example, when polycrystalline silicon is used for forming the lower electrode 9, it is possible to interpose the first dielectric film 3 made of Al₂O₃ between the lower electrode 9 and the ZrO₂ film, so that the ZrO₂ film can be formed with uniform film thickness. Also, when polycrystalline silicon is used for forming the upper electrode 10, it is possible to interpose the third dielectric film 6 made of Al₂O₃ between the upper electrode 10 and the ZrO₂ film, so that the reaction between ZrO₂ and polycrystalline silicon can be suppressed and avoid an increase in a leakage current and a decrease in capacitance.

In the above-mentioned first through third embodiments, Al₂O₃ is used for the amorphous dielectric film and ZrO₂ is used for the crystalline insulating film. However, the present invention is not limited to these embodiments. It is also possible to use a composite dielectric material such as Al₂O₃ to which HfO₂, ZrO₂, La₂O₃, Y₂O₃ and the like is/are added for the amorphous dielectric film. Further, it is possible to use HfO₂, TiO₂, Ta₂O₅, BST (barium strontium titanate), STO (strontium titanate), PZT (lead zirconate titanate) and the like for the crystalline insulating film.

[Embodiment 4]

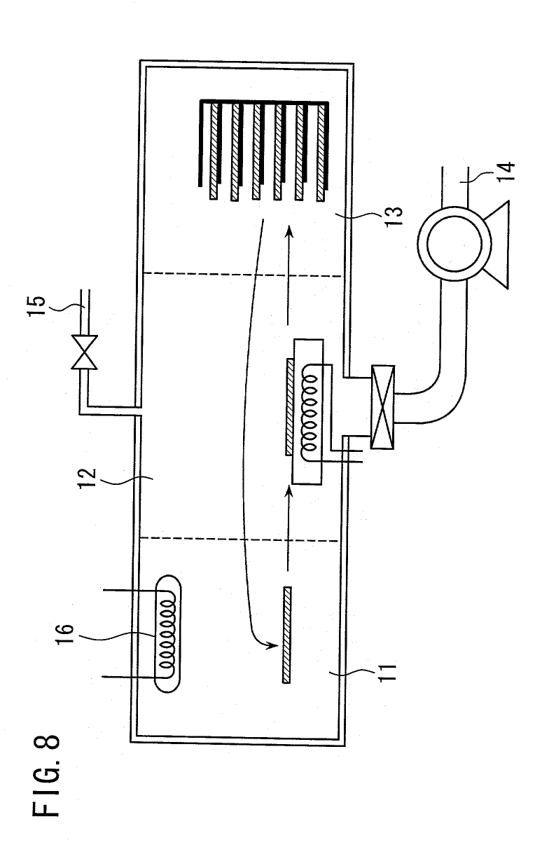

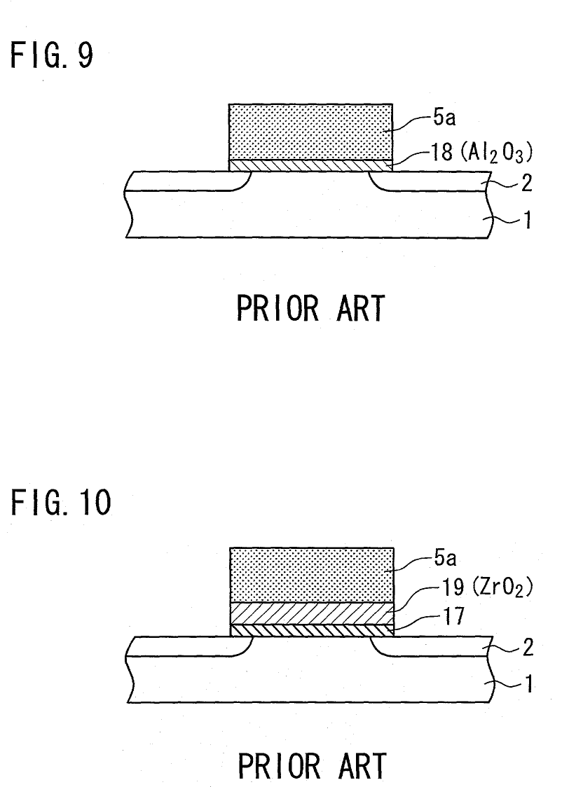

With reference to FIG. 8, an explanation will be made on a new ALD system for forming a thin film having a high dielectric constant, according to the fourth embodiment of the present invention. FIG. 8 is a cross sectional view showing a schematic structure of the new ALD system. The ALD system according to the present embodiment can be used for forming the thin film having a high dielectric constant shown in the embodiments 1-3 described above.

To realize a minute MOSFET, to improve insulation resistance of an insulating film of the MOSFET and to increase capacitance of a capacitor of a DRAM device, the present invention provides a dielectric film having a multi-layer structure and having a high dielectric constant which is formed as a film having small and uniform film thickness. Especially, it is preferable that the thickness of the first dielectric film 3 made of Al₂O₃ which becomes the grounding layer is controlled precisely at an order of angstroms, such that the reduced film thickness of the multi-layer film as a whole can be decreased and the film thickness of the crystalline insulating film such as the ZrO₂ film formed on the grounding layer becomes uniform. Therefore, in order to form such film, it is preferable to use the ALD system which can control the film thickness on an atomic layer level. When the Al₂O₃ film is formed on the silicon substrate by using the ALD system, it is necessary to separate hydrogen which terminates the silicon surface, from the silicon substrate.

Separation of hydrogen from the silicon substrate is performed, for example, at a temperature atmosphere of 400° C. or higher, in a hydrogen separating process. On the other hand, a process of forming the Al₂O₃ film is performed at a temperature of approximately 300° C. If these processes are to be performed continuously by using a conventional ALD equipment, it is necessary to first raise a temperature of a workpiece to 400° C. or higher to perform the hydrogen separation process, and thereafter to wait until the temperature of the workpiece falls to approximately 300° C. to perform the process of forming the Al₂O₃ film. Therefore, in case a series of these processes is performed every wafer, the number of process steps in the ALD system increases and a cost of a semiconductor device increases.

In order to solve such problems, the ALD system according to the present invention comprises, as shown in FIG. 8, a workpiece storing chamber portion 13, a reaction chamber portion 12 and a hydrogen separating chamber portion 11 which communicate with each other. The workpiece storing chamber poprtion 13 stores workpieces before processing and after processing. The reaction chamber portion 12 is a chamber for forming a film of a predetermined material, and has a similar structure of a conventional ALD system. The hydrogen separating chamber portion 11 is a chamber for separating hydrogen from the surface of the silicon substrate 1 and the like, and has a heating lamp 16 for heating a workpiece in the chamber 11. The ALD system of FIG. 8 also comprises a transporting system not shown in the drawing which transports the workpieces, for example, from the workpiece storing chamber portion 13, to the hydrogen separating chamber portion 11, to the reaction chamber portion 12 and again to the workpiece storing chamber portion 13. The ALD system of FIG. 8 further comprises a vacuum pump system 14, a reaction gas supplying system 15 and the like as in the conventional ALD system.

In the ALD system of FIG. 8, a workpiece is first transported from the workpiece storing chamber portion 13 to the hydrogen separating chamber portion 11, and is heated by the heating lamp 16 to perform hydrogen separation process at a temperature of, for example, 400° C. Then, the workpiece is transported to the reaction chamber portion 12 and the dielectric film is formed on the workpiece at a temperature of, for example, 300° C. Therefore, the hydrogen separation process and the film forming process which are to be performed at different temperatures can be performed continuously without exposing the workpiece to the external atmosphere. Also, by providing different chamber portions for performing a pretreatment process and for performing a film forming process, it is becomes possible to perform different processes continuously without waiting until the temperature for each process settles to a desired value and within the same vacuum condition. Therefore, it is possible to decrease the number of processes in fabricating a semiconductor device, and to decrease manufacturing costs of the semiconductor device.

In the above, an explanation was made on the ALD system. However, the present invention can be applied to any other film forming system in which a film forming process and a pretreatment process such as a hydrogen separating process and the like are performed at different temperatures. Especially, the present invention is suitably used for a film forming system in which the temperature of the pretreatment process such as the hydrogen separating process and the like is higher than the temperature of the film forming process. For example, the present invention can also be applied to a low pressure CVD system, an atmospheric pressure CVD system, a plasma CVD system, an epitaxial growth system and the like.

According to the present invention, in a semiconductor device including a thin film having a high dielectric constant and a method of manufacturing the same, the thin film having a high dielectric constant has, as an embodiment thereof, a two layer structure comprising a first dielectric film which is made of amorphous oxide such as aluminum oxide (Al₂O₃) and the like and a second dielectric film which is made of metal oxide such as zirconium oxide (ZrO₂), hafnium oxide (HfO₂), and the like. In other embodiment, the thin film having a high dielectric constant has a three layer structure further comprising a third dielectric film which is formed on the abovementioned second dielectric film and which is made of amorphous oxide such as aluminum oxide (Al₂O₃) and the like. Therefore, it is possible to form a crystalline oxide film without islanding the film and with uniform film thickness. It is also possible to avoid an increase in the SiO₂ reduced film thickness.

The reason for this is as follows. The Al₂O₃ film functions as a seed layer for the ZrO₂ film, and, therefore, it is possible to grow the ZrO₂ film uniformly. Also, the Al₂O₃ film functions as an oxygen barrier and, therefore, oxygen is not supplied to the silicon substrate or the polycrystalline silicon film. Therefore, it is possible to suppress formation of a silicon oxide film at the interface between the Al₂O₃ film and the silicon substrate and the like.

Also, by using the three layer structure comprising amorphous oxide such as aluminum oxide (Al₂O₃) and the like/metal oxide such as zirconium oxide (ZrO₂) and the like/amorphous oxide such as aluminum oxide (Al₂O₃) and the like, it is possible to suppress an increase in a leakage current and a decrease in a capacitance value.

The reason for this is as follows. By disposing the Al₂O₃ film on the ZrO₂ film, it is possible to prevent the ZrO₂ film from being exposed to a reducing atmosphere when a polycrystalline silicon layer or SiGe layer is formed thereafter. It is also possible to suppress reaction between Si and Zr in an impurity ion implantation process and a heat treatment process.

Further, according to the film forming system for forming a thin film having a high dielectric constant of the present invention, it is possible to decrease the number of process steps in a hydrogen separating process and a thin dielectric film forming process, and to decrease manufacturing costs of a semiconductor device.

This is because, in the ALD system according to the present invention, a hydrogen separating chamber portion is additionally provided adjacently to a reaction chamber portion, and, in the hydrogen separating chamber portion, hydrogen is separated from the silicon substrate and the like by using, for example, a heating lamp. Workpieces are transported one after another from the hydrogen separating chamber portion to the reaction chamber portion. Therefore, even if heating temperatures differ between the hydrogen separating process and the film forming process, it is not necessary to wait until each temperature is settled to a desired value, but it is possible to perform the processes continuously.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative sense rather than a restrictive sense, and all such modifications are to be included within the scope of the present invention. Therefore, it is intended that this invention encompasses all of the variations and modifications as falling within the scope of the appended claims.

What is claimed is:

1. A semiconductor device comprising:
a silicon layer; and
an electrode which is made of a metal or a metal nitride and which is formed on the silicon layer via a dielectric film interposed therebetween;
wherein the dielectric film has a multi-layer structure comprising an amorphous oxide film on the side of the silicon layer and a metal oxide film on the side of the electrode.

2. A semiconductor device as set forth in claim 1, wherein the amorphous oxide film is made of a metal oxide selected from a group including at lease Al₂O₃.

3. A semiconductor device as set forth in claim 2, wherein the thickness of the amorphous oxide film is in a range of 2-20 angstroms.

4. A semiconductor device as set forth in claim 2, wherein the thickness of the amorphous oxide film is in a range of 5-10 angstroms.

5. A semiconductor device as set forth in claim 1, wherein the metal oxide film comprises a stack of one or more films of materials selected from a group consisting of ZrO₂, HfO₂, TiO₂, Ta₂O₅, BST, STO, PZT and mixtures of these materials with Al₂O₃.

6. A semiconductor device as set forth in claim 5, wherein the thickness of the metal oxide film is in a range of 10-50 angstroms.

7. A semiconductor device as set forth in claim 1, wherein the metal oxide film or the amorphous oxide film disposed on the side of the silicon layer is formed by using an ALD system.

8. A semiconductor device as set forth in claim 1, wherein the dielectric film is formed as a gate insulating film of a MOSFET in the semiconductor device.

9. A semiconductor device as set forth in claim 1, wherein the semiconductor device is a DRAM device and the dielectric film is formed as an insulating film of a capacitor of the DRAM device.

10. A semiconductor device comprising:
a silicon layer; and
an electrode which is made of silicon (Si) or silicon germanium (SiGe) and which is formed on the silicon layer via a dielectric film interposed therebetween;
wherein the dielectric film has a multi-layer structure comprising a first amorphous oxide film on the side of the silicon layer, a second amorphous oxide film on the side of the electrode, and a metal oxide film interposed between the first and second amorphous oxide films.

11. A semiconductor device as set forth in claim 10, wherein the first amorphous oxide film is made of a metal oxide selected from a group including at least SiO₂ and Al₂O₃, and wherein the second amorphous oxide film is made of a metal oxide selected from a group including at least Al₂O₃.

12. A semiconductor device as set forth in claim 11, wherein the thickness of the first or second amorphous oxide films is in a range of 2-20 angstroms.

13. A semiconductor device as set forth in claim 11, wherein the thickness of the first or second amorphous oxide films is in a range of 5-10 angstroms.

14. A semiconductor device as set forth in claim 10, wherein the metal oxide film comprises a stack of one or more films of materials selected from a group consisting of ZrO₂, HfO₂, TiO₂, Ta₂O₅, BST, STO, PZT and mixtures of these materials with Al₂O₃.

15. A semiconductor device as set forth in claim 14, wherein the thickness of the metal oxide film is in a range of 10-50 angstroms.

16. A semiconductor device as set forth in claim 10, wherein the metal oxide film or at least the first amorphous oxide film disposed on the side of the silicon layer is formed by using an ALD system.

17. A semiconductor device as set forth in claim 10, wherein the dielectric film is formed as a gate insulating film of a MOSFET in the semiconductor device.

18. A semiconductor device as set forth in claim 10, wherein the semiconductor device is a DRAM device and the dielectric film is formed as an insulating film of a capacitor of the DRAM device.

19. A method of manufacturing a semiconductor device having a silicon layer, an electrode which is made of a metal or a metal nitride and which is formed on the silicon layer via a dielectric film interposed therebetween, wherein the dielectric film has a multi-layer structure comprising an amorphous oxide film on the side of the silicon layer and a metal oxide film on the side of the electrode, said method comprising:
before forming the amorphous oxide film, terminating the surface of the silicon layer with hydrogen; and
after separating hydrogen from the surface of the silicon layer, forming the amorphous oxide film on the silicon layer.

20. A method of manufacturing a semiconductor device as set forth in claim 19, wherein the separating hydrogen from the surface of the silicon layer and the forming the amorphous oxide are performed within a common chamber.

21. A method of manufacturing a semiconductor device as set forth in claim 19, wherein the amorphous oxide film is made of a metal oxide selected from a group including at least Al₂O₃.

22. A method of manufacturing a semiconductor device as set forth in claim 19, wherein the metal oxide film comprises a stack of one or more films of materials selected from a group consisting of ZrO₂, HfO₂, TiO₂, Ta₂O₅, BST, STO, PZT and mixtures of these materials with Al₂O₃.

23. A method of manufacturing a semiconductor device as set forth in claim 19, wherein the metal oxide film or the amorphous oxide film disposed on the side of the silicon layer is formed by using an ALD system.

24. A method of manufacturing a semiconductor device as set forth in claim 19, wherein the dielectric film is formed as a gate insulating film of a MOSFET in the semiconductor device.

25. A semiconductor device as set forth in claim 19, wherein the semiconductor device is a DRAM device and the dielectric film is formed as an insulating film of a capacitor of the DRAM device.

26. A method of manufacturing a semiconductor device having a silicon layer, an electrode which is made of silicon (Si) or silicon germanium (SiGe) and which is formed on the silicon layer via a dielectric film interposed therebetween, wherein the dielectric film has a multi-layer structure comprising a first amorphous oxide film on the side of the silicon layer, a second amorphous oxide film on the side of the electrode, and a metal oxide film interposed between the first and second amorphous oxide films, said method comprising:
before forming the first amorphous oxide film, terminating the surface of the silicon layer with hydrogen; and
after separating hydrogen from the surface of the silicon layer, forming the first amorphous oxide film on the silicon layer.

27. A method of manufacturing a semiconductor device as set forth in claim 26, wherein the separating hydrogen from the surface of the silicon layer and the forming the first amorphous oxide film are performed within a common chamber.

28. A method of manufacturing a semiconductor device as set forth in claim 26, wherein the first amorphous oxide film is made of a metal oxide selected from a group including at least SiO₂ and Al₂O₃, and wherein the second amorphous oxide film is made of a metal oxide selected from a group including at least Al₂O₃.

29. A method of manufacturing a semiconductor device as set forth in claim 26, wherein the metal oxide film comprises a stack of one or more films of materials selected from a group consisting of ZrO₂, HfO₂, TiO₂, Ta₂O₅, BST, STO, PZT and mixtures of these materials with Al₂O₃.

30. A method of manufacturing a semiconductor device as set forth in claim 26, wherein the metal oxide film or the first amorphous oxide film disposed on the side of the silicon layer is formed by using an ALD system.

31. A method of manufacturing a semiconductor device as set forth in claim 26, wherein the dielectric film is formed as a gate insulating film of a MOSFET in the semiconductor device.

32. A method of manufacturing a semiconductor device as set forth in claim 26, wherein the semiconductor device is a DRAM device and the dielectric film is formed as an insulating film of a capacitor of the DRAM device.

33. A system for forming a dielectric film comprising:
a heating chamber portion for separating hydrogen which terminates a surface of a workpiece of a semiconductor device; and
a film forming chamber portion for forming the dielectric film on the surface of the workpiece on an atomic layer level;
wherein the heating chamber portion and the film forming chamber portion communicate with each other, and a process of separating hydrogen from the surface of the workpiece and a process of forming the dielectric film on the surface of the workpiece can be performed continuously.
